(19) United States
(12) Patent Application Publication
(10) Pub. No.: US 2012/0006385 A1
(43) Pub. Date: Jan. 12, 2012

(54) High Performance Multi-Layer Back Contact Stack For Silicon Solar Cells

(75) Inventors: Mohd Fadzli Anwar Hassan, Sunnyvale, CA (US); Hien-Minh Huu Le, San Jose, CA (US)

(73) Assignee: Applied Materials, Inc., Santa Clara, CA (US)

(21) Appl. No.: 13/170,639

(22) Filed: Jun. 28, 2011

Related U.S. Application Data
(60) Provisional application No. 61/362,836, filed on Jul. 9, 2010.

(51) Int. Cl. H01L 31/052; H01L 31/0216; H01L 31/18; H01L 31/0224

(52) U.S. Cl. 136/246; 136/256; 438/72; 257/E31.127

(57) ABSTRACT

High performance multi-layer back contact stacks for silicon solar cells and methods for manufacture are disclosed. Photovoltaic modules incorporating high performance multi-layer back contact stacks and methods for making the same are also described.

### CROSS-REFERENCE TO RELATED APPLICATIONS

This application claims the benefit of U.S. Patent Application No. 61/362,836, filed on Jul. 9, 2010.

### BACKGROUND

Embodiments of the present invention generally relate to photovoltaic modules and methods of making photovoltaic modules. Specific embodiments pertain to photovoltaic modules, photovoltaic cells incorporating a multi-layer back contact stack and methods of making the same.

In thin film solar cells, also called photovoltaic cells, reflection of initially-unabsorbed light from the back contact allows for additional absorption in the cell to increase device current, and conversion efficiency. The use of zinc oxide (ZnO) with a silver stack layer for Tandem Junction solar cells yields the highest bottom cell current for physical vapor deposition (PVD) produced back contact stacks.

However, silver has poor adhesion to aluminum doped zinc oxide (AZO), a commonly used back contact conducting layer. Therefore, to reduce delamination at the interface of the AZO and silver layers, an active metal layer is often used. This active metal layer, also called a “glue layer”, is generally a thin layer including chromium, titanium, tantalum or other active metals. The purpose of this metal layer is to improve interface strength (i.e., adhesion) between the AZO layer and the silver layer. Due to the introduction of this glue layer between the AZO and silver layers, some light is absorbed and, therefore, the reflection from the silver layer is reduced. This reduced reflection causes a decrease in the current produced by the photovoltaic cell.

Without the glue layer, the adhesion of the silver layer to the AZO layer is, technically speaking, sufficient to provide good device performance with the highest current and best conversion efficiency. The biggest problem occurs during the soldering process employed to connect a busswire to the back contact. During this soldering, the back contact is subjected to high temperature (greater than about 380° C.) and solder flux material, a potentially corrosive chemical, which causes delamination between the AZO and silver interface.

Delamination is not solely due to poor adhesion (interface strength) between AZO and the silver layers, but due to other factors as well. The factors that affect the delamination include, in no particular order: (1) interface strength (adhesion between the AZO layer and the silver layer; (2) high temperatures applied to the back contact during soldering causing film cracks along grain boundaries; (3) the corrosive flux used during soldering; (4) a combination of high temperature during soldering and the corrosive flux reacting with the silver and causing delamination at the AZO interface; and (5) film stress mismatch between films in the back contact stack causes sever delamination and flux penetration (and corrosion) during soldering due to thermal stress, resulting in delamination at the AZO—silver interface.

Therefore, there is a need in the art for back contact stacks and methods of making back contact stacks that resist delamination at the AZO—silver interface while maximizing the reflection of initially-unabsorbed light from the silver layer.

### SUMMARY OF THE INVENTION

One or more embodiments of the invention are directed to a back contact for a photovoltaic cell. The back contact comprises a back contact conductive layer in contact with a photovoltaic cell conductive layer, a reflective layer on the back contact conductive layer; a barrier layer on the reflective layer; and a passivation layer on the barrier layer. The passivation layer has a similar coefficient of thermal expansion as a busswire which connects the back contact of the photovoltaic cell to at least one adjacent photovoltaic cell.

In some embodiments there is no intervening layer between the conductive layer and the reflective layer.

The conductive layer of detailed embodiments comprises ZnO:Al. The reflective layer of one or more embodiments comprises silver. The barrier layer of various embodiments comprises a metal selected from the group consisting of chromium, tantalum, titanium, nickel, palladium and cobalt. In specific embodiments, the barrier layer comprises titanium.

In one or more embodiments, the passivation layer comprises a first sublayer and a second sublayer. The first sublayer of specific embodiments comprises aluminum. The first sublayer of some embodiments has a thickness greater than about 500 Å. In detailed embodiments, the second sublayer comprises nickel vanadium. The second sublayer of some embodiments has a thickness in the range of about 350 Å to about 1000 Å. In some embodiments, the passivation layer comprises an aluminum alloy.

In specific embodiments, there is substantially no delamination of the reflective layer from the conductive layer upon attaching the busswire to the back contact.

Additional embodiments of the invention are directed to a photovoltaic module comprising a plurality of photovoltaic cells. Each cell comprising a front contact; a light absorbing layer comprising one or more of an n-type layer, a p-type layer and an intrinsic layer and a back contact. The back contact comprises a conductive layer in contact with the photovoltaic cell, a reflective layer on the conductive layer, a barrier layer on the reflective layer and a passivation layer on the barrier layer. A busswire connects adjacent photovoltaic cells, the busswire being connected to the passivation layer of the back contact.

In specific embodiments, the back contact does not have a glue layer between the conductive layer and the reflective layer. In detailed embodiments, there is substantially no delamination of the reflective layer from the conductive layer.

In some embodiments, the conductive layer comprises ZnO:Al, the reflective layer comprises silver, and the barrier layer comprises titanium. The passivation layer of one or more embodiments comprises a first sublayer comprising aluminum and a second sublayer comprising nickel vanadium. The passivation layer of various embodiments comprises an aluminum alloy.

Further embodiments of the invention are directed to a method of manufacturing a solar cell. A solar film is deposited onto a superstrate. The solar film is adapted to convert light energy into electrical current. The solar film includes a front contact and at least one light absorbing layer. A back contact conductive layer is deposited on the solar film. A reflector layer is deposited on the back contact layer. A barrier layer is deposited on the reflector layer. A passivation layer is deposited on the barrier layer. A busswire is soldered to the solar cell over the passivation layer. Soldering the busswire to the solar cell occurs at a temperature in the range of 350° C. to about 400° C. and causes substantially no delamination of the reflector layer from the back contact conductive layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A shows a process for making photovoltaic modules according to one or more embodiments of the invention;

FIG. 1B show a cross-sectional view of a process for making photovoltaic modules according to one or more embodiments of the invention;

FIG. 2A is a side cross-sectional view of a thin film photovoltaic modules according to one or more embodiment of the invention;

FIG. 2B is a side cross-sectional view of a thin film photovoltaic modules according to one or more embodiment of the invention;

FIG. 3 shows a photovoltaic cell according to one or more embodiments of the invention;

FIG. 4 shows a photovoltaic module according to one or more embodiments of the invention;

FIG. 5 is a plan view of a composite photovoltaic module according to one or more embodiment of the invention;

FIG. 6 is a side cross-sectional view along Section 6-6 of FIG. 5; and

FIG. 7 is a side cross-sectional view along Section 7-7 of FIG. 5.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. For example, reference to a “cell” may also refer to more than one cells, and the like.

The term “photovoltaic cell” is used to describe an individual stack of layers suitable for converting light into electricity. The term “photovoltaic module” is used to describe a plurality of photovoltaic cells connected in series.

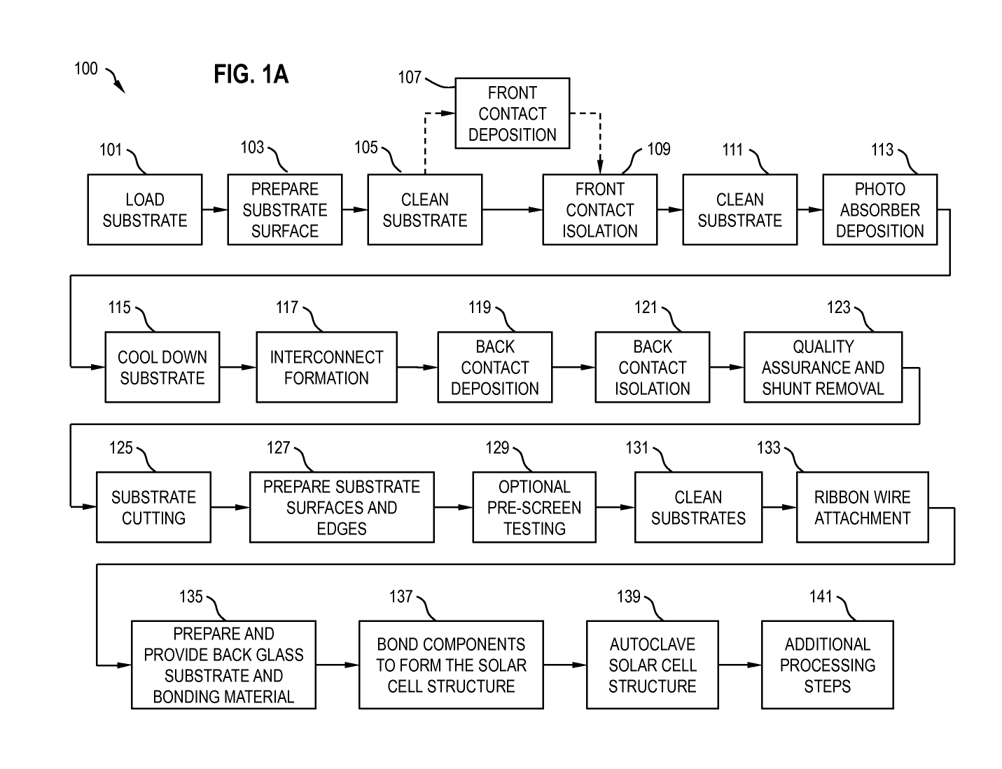

FIGS. 1A and 1B illustrate a typical process sequence 100 used in the manufacture of solar cells. It is to be understood that the invention is not limited to the process sequence illustrated and described below. Other manufacturing processes can be employed without deviating from the spirit and scope of the invention.

The process sequence 100 generally starts at step 101 in which a superstrate 102 is loaded into a loading module. The superstrate 102 may be received in a “raw” state where the edges, overall size, and/or cleanliness of the substrates are not well controlled. Receiving “raw” substrates reduces the cost to prepare and store substrates prior to forming a solar module and thus reduces the solar cell module cost, facilities costs, and production costs of the finally formed solar cell module. However, typically, it is advantageous to receive “raw” substrates that have a transparent conducting oxide (TCO) layer already deposited on a surface of the superstrate 102 before it is received into the system in step 101. If a front contact layer 110, such as TCO layer, is not deposited on the surface of the “raw” superstrate 102 then a front contact deposition step (step 107), which is discussed below, needs to be performed on a surface of the superstrate 102. By either name, it is meant as a surface with may ultimately face a light source (i.e., the sun). The superstrate 102 allows for the transmission of substantially all incident light 198 having wavelengths that can be absorbed by a light absorbing layer 120. As used in this specification and the appended claims, the term “substantially all incident light having wavelengths that can be absorbed by a light absorbing layer” means that the superstrate absorbs less than about 10% of the usable incident light.

The superstrate 102 is often made of glass, but other materials including, but not limited to, polymeric materials can be employed. Additionally, the superstrate 102 can be made of a rigid or flexible material. An exemplary thickness for a glass sheet is about 3 mm. In the art, this superstrate 102 may be referred to as a substrate because a plurality of material layers are deposited onto the superstrate 102. The specific choice of superstrate 102 material should not be taken as limiting the scope of the invention.

In step 103, the surfaces of the superstrate 102 are prepared to prevent yield issues later in the process. The superstrate 102 may be inserted into a front end substrate seaming module that is used to prepare the edges of the superstrate 102 to reduce the likelihood of damage, such as chipping or particle generation from occurring during the subsequent processes. Damage to the superstrate 102 can affect module yield and the cost to produce a usable photovoltaic module.

Next, the superstrate 102 is cleaned (step 105) to remove any contaminants found on the surface. Common contaminants may include materials deposited on the superstrate 102 during the substrate forming process (e.g., glass manufacturing process) and/or during shipping or storing of the substrates 102. Typically, cleaning uses wet chemical scrubbing and rinsing steps to remove any undesirable contaminants, but other cleaning processes can be employed.

If the superstrate 102 loaded in step 101 does not have a front contact layer 110 on the surface, a front contact layer 110 is deposited in step 107. The front contact layer 110 is often a transparent conductive oxide (TCO) layer, and may be referred to as a “first TCO layer” throughout this specificiation. The superstrate 102 may be transported to a front end processing module in which a front contact formation process, step 107, is performed on the superstrate 102. In step 107, the one or more substrate front contact formation steps may include one or more of preparation, etching, and/or material deposition steps to form the front contact regions on a bare superstrate 102. Step 107 may comprise one or more physical vapor deposition (PVD) steps or chemical vapor deposition (CVD) steps that are used to form the front contact region on a surface of the superstrate 102.

Suitable materials for the front contact layer 110 include, but are not limited to, aluminum-doped zinc oxide (AZO), indium tin oxide (ITO), indium molybdenum oxide (IMO), indium zinc oxide (IZO) and tantalum oxide. In some embodiments, the front contact region may contain a transparent conducting oxide (TCO) layer 110 that contains a metal element selected from a group consisting of zinc (Zn), aluminum (Al), indium (In), tantalum (Ta) molybdenum (Mo) and tin (Sn). In a specific embodiment, zinc oxide (ZnO) is used to form at least a portion of the front contact layer 110.

In step 109, separate cells are electrically isolated from one another via scribing processes. Contamination particles on the front contact layer 110 surface and/or on the bare glass superstrate 102 surface can interfere with the scribing procedure. In laser scribing, for example, if the laser beam runs across a particle, it may be unable to scribe a continuous line, resulting in a short circuit between cells. In addition, any particulate debris present in the scribed pattern and/or on the front contact layer 110 of the cells after scribing can cause shunting and non-uniformities between layers.

The device superstrate 102 is transported to the scribe module in which step 109, or a front contact isolation step, is performed on the device superstrate 102 to electrically isolate different regions of the device superstrate 102 surface from each other. In step 109, material is removed from the device superstrate 102 surface by use of a material removal step, such as a laser ablation process. The success criteria for step 109 are to achieve good cell-to-cell and cell-to-edge isolation while minimizing the scribe area. The front contact isolation step 109 uses a laser scribing process, often referred to as P1, which scribes strips 104 through the entire thickness of the front contact layer 110. The scribed strips are usually 5-10 mm apart, but larger and smaller distances can be used.

Next, the device superstrate 102 is transported to a cleaning module in which step 111, a pre-deposition substrate cleaning step, is performed on the device superstrate 102 to remove any contaminants found on the surface of the device superstrate 102 after performing the cell isolation step 109. Typically, cleaning uses wet chemical scrubbing and rinsing steps to remove any undesirable contaminants found on the device superstrate 102 surface after performing the cell isolation step.

Next, the device superstrate 102 is transported to a processing module in which step 113, which comprises one or more photoabsorber layer 120 deposition steps, is performed on the device superstrate 102. The terms “photoabsorber layer”, “light absorbing layer” and “solar film” are used interchangeably throughout this specification and refer to an individual layer or combination of layers which are effective to convert electromagnetic radiation (light energy) to electrical current. In step 113, the one or more photoabsorber layer 120 deposition steps may include one or more of preparation, etching, and/or material deposition steps that are used to form the various regions of the solar cell device.

Non-limiting examples of suitable light absorbing layers 104 include amorphous silicon, microcrystalline silicon, germanium compositions and doped materials with varying bandgaps. The light absorbing layer 120 can be any layer or combination of layers known to those skilled in the art that are effective and should not be taken as limiting the scope of the invention. In specific embodiments, the light absorbing layer 120 comprises a plurality of individual sub-layers which, in combination, makes either a single-junction or tandem-junction photovoltaic. In specific embodiments, the light absorbing layer comprises one or more of an n-type, a p-type and an intrinsic layer.

The light absorbing layer 120, including any individual sublayers, can be deposited on the superstrate 102 by any suitable means known to those skilled in the art. Suitable examples include, but are not limited to, physical vapor deposition techniques, including plasma enhanced techniques and chemical vapor deposition techniques.

A cool down step, or step 115, may be performed after step 113. The cool down step is generally used to stabilize the temperature of the device superstrate 102 to assure that the processing conditions seen by each device superstrate 102 in the subsequent processing steps are repeatable. Generally, the temperature of the device superstrate 102 exiting a processing module can vary by many degrees and exceed a temperature of 50° C., which can cause variability in the subsequent processing steps and solar cell performance.

Next, the device superstrate 102 is transported to a scribe module in which step 117, or the interconnect formation step, is performed on the device superstrate 102 to electrically isolate various regions of the device superstrate 102 surface from each other. In step 117, material is removed from the device superstrate 102 surface by use of a material removal step, such as a laser ablation process. This second laser scribing step, often referred to as P2, completely cuts strips 108 through the photoabsorber layer 120.

Next, the device superstrate 102 may be subjected to one or more substrate back contact formation steps, or step 119. In step 119, a back contact stack 165, which often includes a plurality of individual layers, is created. A back contact conductive layer 130, which may be a second TCO layer, is commonly formed on the photoabsorber layer 120. The back contact stack 165 formation steps may include one or more of preparation, etching, and/or material deposition steps that are used to form the back contact regions of the solar module. Step 119 generally comprises one or more PVD steps or CVD steps that are used to form the back contact stack 165 on the surface of the photoabsorber layer 120. In detailed embodiments, the one or more PVD steps are used to form a back contact stack 165 that contains a metal layer selected from a group consisting of zinc (Zn), tin (Sn), aluminum (Al), copper (Cu), silver (Ag), nickel (Ni), vanadium (V), molybdenum (Mo), and conductive carbon. The individual layers often included in a back contact stack 165 are described in further detail below.

Next, the device superstrate 102 is transported to a scribe module in which step 121, or a back contact isolation step, is performed on the device superstrate 102 to electrically isolate the plurality of solar cells contained on the substrate surface from each other. In step 121, material is removed from the substrate surface by use of a material removal step, such as a laser ablation process. This third scribing process, called P3, is used to scribe strips 112 through the back contact conductive layer 130 and the photoabsorber layer 120. The area between, and including, the P1 and P3 scribes results in a dead zone 114 which decreases the overall efficiency of the cell. The dead zone is typically in the range of about 100 μm to about 500 μm, depending on the accuracy of the lasers and optics employed in the scribing processes.

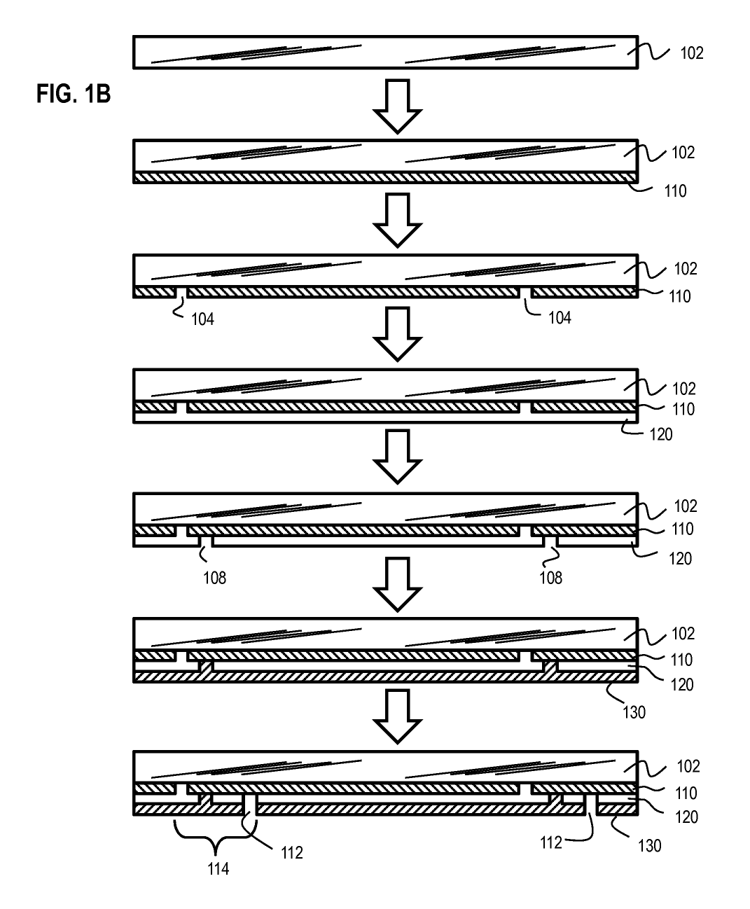

FIG. 2A shows a single junction amorphous silicon photovoltaic cell 104. The photovoltaic cell 104 shown comprises a superstrate 102 such as a glass substrate, polymer substrate, metal substrate, or other suitable substrate, with thin films formed thereon. In a specific embodiment, the superstrate 102 is a glass substrate that is about 2200 mm×2600 mm×3 mm in size. The solar cell 104 further comprises a first transparent conducting oxide (TCO) layer 110 (e.g., zinc oxide (ZnO), tin oxide (SnO)) formed over the superstrate 102, a first photoabsorber layer 120, comprising a p-i-n junction, formed over the front contact layer 110. A back contact conductive layer 130 is formed over the first photoabsorber layer 120, and a back contact stack 165 is formed over the back contact conductive layer 130. Although the back contact conductive layer 130 and the back contact stack 165 are discussed separately in this figure, it should be understood that the back contact conductive layer 130 is considered part of the back contact stack 165. To improve light absorption by enhancing light trapping, the superstrate 102 and/or one or more of the thin films formed thereover may be optionally textured by wet, plasma, ion, and/or mechanical processes. For example, in the embodiment shown in FIG. 2A, the front contact layer 110 is textured, and the subsequent thin films deposited thereover generally follow the topography of the surface below it.

In the detailed embodiment shown in FIG. 2A, the first photoabsorber layer 120 comprises a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. The p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type microcrystalline silicon layer 126 may be formed to a thickness between about 100 Å and about 400 Å. The back contact conductive layer 130 is deposited over the photoabsorber layer 120 and is often a second transparent conductive oxide layer. A reflective layer 150 is deposited over the back contact conductive layer 130. The reflective layer 150 is a sublayer in a back contact stack 165, which can also include the back contact conductive layer 130. The reflective layer 150 may include, but is not limited to, a material selected from the group consisting of Al, Ag, Ti, Cr, Au, Cu, Pt, Ni, Mo, conductive carbon, alloys thereof, and combinations thereof. In detailed embodiments, the reflective layer 150 comprises one or more of a paint layer, a polymer layer impregnated with a white pigment, and a metal selected from the group consisting of silver, copper and combinations thereof.

FIG. 2B is a schematic diagram of an embodiment of a solar cell 104, which is a multi-junction solar cell. The solar cell 104 of FIG. 2B comprises a superstrate 102, such as a glass substrate, polymer substrate, metal substrate, or other suitable substrate, with thin films formed thereover. The solar cell 104 may further comprise a first transparent conducting oxide (TCO) layer 110 formed over the superstrate 102, a first photoabsorber layer 120 formed over the front contact layer 110, a second photoabsorber layer 160 formed over the first photoabsorber layer 120, a back contact conductive layer 130 formed over the second photoabsorber layer 160, and a reflective layer 150 formed over the back contact conductive layer 130.

In the embodiment shown in FIG. 2B, the front contact layer 110 is textured, and the subsequent thin films deposited thereover generally follow the topography of the surface below it. The first photoabsorber layer 120 may comprise a p-type amorphous silicon layer 122, an intrinsic type amorphous silicon layer 124 formed over the p-type amorphous silicon layer 122, and an n-type microcrystalline silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type microcrystalline silicon layer 126 may be formed to a thickness between about 100 Å and about 400 Å.

The second photoabsorber layer 160 may comprise a p-type microcrystalline silicon layer 162, an intrinsic type microcrystalline silicon layer 164 formed over the p-type microcrystalline silicon layer 162, and an n-type amorphous silicon layer 166 formed over the intrinsic type microcrystalline silicon layer 164. In one example, the p-type microcrystalline silicon layer 162 may be formed to a thickness between about 100 Å and about 400 Å, the intrinsic type microcrystalline silicon layer 164 may be formed to a thickness between about 10,000 Å and about 30,000 Å, and the n-type amorphous silicon layer 166 may be formed to a thickness between about 100 Å and about 500 Å. The reflective layer 150 may include, but is not limited to a material selected from the group consisting of Al, Ag, Ti, Cr, Au, Cu, Pt, Ni, Mo, conductive carbon, alloys thereof, and combinations thereof.

A back contact stack 165, is positioned over the light absorbing layer 120. The back contact stack 165 includes layers suitable for reflecting unabsorbed light transmitted through the light absorbing layer 120, and provides a contact point for a busswire 120. A back contact conductive layer 130 is positioned over the light absorbing layer 120.

A reflective layer 150 is deposited over the back contact conductive layer 130. The reflective layer 150 is made of a material suitable for reflecting light 198 not initially absorbed by the light absorbing layer 120. The reflective layer provides tensile stress to the back contact stack 165. In detailed embodiments, the reflective layer 150 comprises silver.

Conventionally, the reflective layer 150 is not deposited directly over the back contact conductive layer 130 because the reflective material may not adhere well to the conductive material, i.e., the reflective layer 150 delaminates from the back contact conductive layer 130. This adherence issue is especially prevalent after connecting a busswire to the solar cell using high temperature and/or soldering flux. However, the back contact stack 165 described herein is capable of withstanding both high temperature and flux during soldering. As such, specific embodiments of the invention have the reflective layer 150 deposited directly over the back contact conductive layer 130, with no intervening layer. In specific embodiments, there is substantially no delamination of the reflective layer 150 from the conductive layer 130 upon attaching the busswire (either a side-buss or a cross-buss) to the back contact stack 165.

A barrier layer 175 is deposited over the reflective layer 150. The barrier layer is a high density metal or compound capable of preventing diffusion of the layer directly on it. The barrier layer 175 can be a continuous layer without a minimum or maximum thickness. In detailed embodiments, the barrier layer 175 is selected from the group consisting of chromium, tantalum, titanium, nickel, palladium, cobalt and combinations thereof. In specific embodiments, the barrier layer 175 comprises titanium.

A passivation layer 184 is deposited on the barrier layer 175. In detailed embodiments, the passivation layer 184 is made of a material having a similar coefficient of thermal expansion as a busswire 195 connected to the back contact stack 165. As used in this specification and the appended claims, the term “similar coefficient of thermal expansion” means that the CTE of the layers differ by no more than about 50%. In more detailed embodiments, similar means that the CTE of the layers differs by less than about 30%, 25%, 20%, 15%, 10%, 5%, 2.5% or 1%. The passivation layer 184 provides compressive stress to the back contact and can be a single layer or a combination of multiple layers.

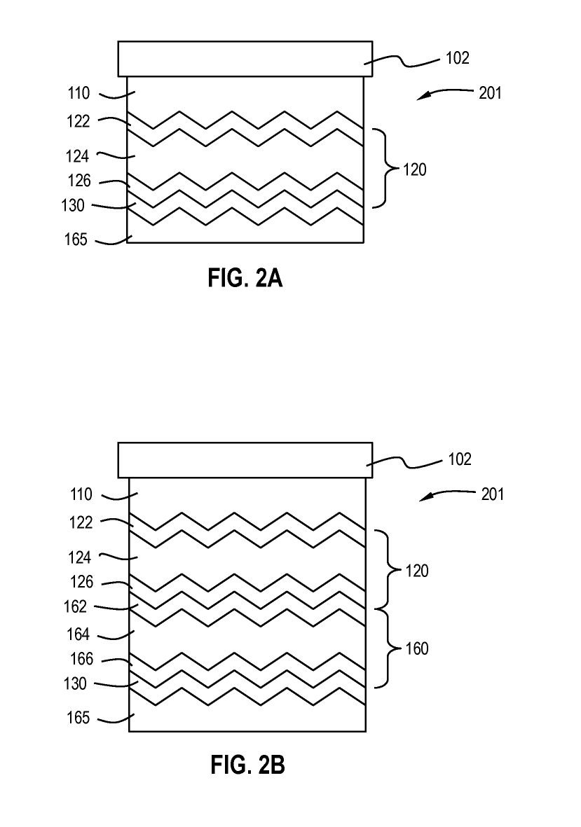

The embodiment shown in FIG. 3 comprises a first sublayer 186 and a second sublayer 188. In detailed embodiments, the first sublayer 186 comprises aluminum. The aluminum first sublayer 186 adds compressive stress to the back contact stack 165. In detailed embodiments, the thickness of the first sublayer 186 is greater than about 500 Å. In specific embodiments, the thickness of the first sublayer 186 is greater than about 200 Å, 250 Å, 300 Å, 350 Å, 400 Å, 450 Å, 500 Å, 550 Å, 600 Å, 650 Å, 700 Å or 750 Å.

The second sublayer 188 may add tensile stress to the back contact stack 165. In specific embodiments, the second sublayer 188 comprises nickel vanadium. The second sublayer 188 of detailed embodiments has a thickness in the range of about 350 Å to about 1000 Å. In one or more embodiments, the thickness of the second sublayer 188 is greater than about 350 Å, 400 Å, 450 Å, 500 Å, 550 Å, 600 Å, 650 Å, 700 Å, 750 Å, 800 Å, 850 Å, 900 Å, 950 Å or 1000 Å.

In various embodiments, the passivation layer 184 comprises a single layer. In detailed embodiments, the single layer passivation layer 184 comprises an aluminum alloy.

Next, the device superstrate 102 is transported to a quality assurance module in which step 123, or quality assurance and/or shunt removal steps, are performed on the device superstrate 102 to assure that the devices formed on the substrate surface meet a desired quality standard and in some cases correct defects in the formed device. In step 123, a probing device is used to measure the quality and material properties of the formed photovoltaic module by use of one or more substrate contacting probes.

Next, the device superstrate 102 is optionally transported to a substrate sectioning module in which a substrate sectioning step 125 is used to cut the device superstrate 102 into a plurality of smaller devices to form a plurality of smaller photovoltaic modules. Instead of directly cutting the device superstrate 102 into smaller sections, the substrate sectioning step 125 may form a series of scored lines. The device superstrate 102 may then be broken along the scored lines to produce the desired size and number of sections needed for the completion of the solar cell devices.

The superstrate 102 is next transported to a seamer/edge deletion module in which a substrate surface and edge preparation step 127 is used to prepare various surfaces of the device superstrate 102 to prevent yield issues later on in the process. Damage to the device superstrate 102 edge can affect the device yield and the cost to produce a usable solar cell device. The seamer/edge deletion module may be used to remove deposited material from the edge of the device superstrate 102 (e.g., 10 mm) to provide a region that can be used to form a reliable seal between the device superstrate 102 and the backside glass (i.e., steps 137 and 139 discussed below). Material removal from the edge of the device superstrate 102 may also be useful to prevent electrical shorts in the final formed solar cell.

The device superstrate 102 is then transported to a pre-screen module in which optional pre-screen steps 129 are performed on the device superstrate 102 to assure that the devices formed on the substrate surface meet a desired quality standard. In step 129, a light emitting source and probing device may be used to measure the output of the formed solar cell device by use of one or more substrate contacting probes. If the module detects a defect in the formed device it can take corrective actions or the solar cell can be scrapped.

Next the device superstrate 102 is transported to a cleaning module in which step 131, or a pre-lamination substrate cleaning step, is performed on the device superstrate 102 to remove any contaminants found on the surface of the substrates 102 after performing the preceding steps. Typically, the cleaning uses wet chemical scrubbing and rinsing steps to remove any undesirable contaminants found on the substrate surface after performing the cell isolation step.

The superstrate 102 may then be transported to a bonding wire attach module in which a bonding (or ribbon) wire attach step 133 is performed on the superstrate 102. Step 133 is used to attach the various wires/leads required to connect various external electrical components to the formed solar cell module. The bonding wire attach module may be an automated wire bonding tool that reliably and quickly forms the numerous interconnects required to produce large solar cells.

A busswire 195 (either a cross-buss or a side-buss) is connected to the passivation layer 184. As used in this specification and the appended claims, the term “busswire” is not limited to wires, but includes bars and three-dimensional structures associated with a buss connection. The busswire 195 can be attached by any suitable means. In detailed embodiments, the busswire 195 is soldered to the solar cell over the passivation layer 184. In specific embodiments, soldering the busswire 195 occurs at a temperature in the range of 350° C. to about 400° C.

In further specific embodiments, the act of soldering the busswire 195 to the passivation layer 184 causes substantially no delamination of the reflector layer 150 from the back contact conductive layer 130.

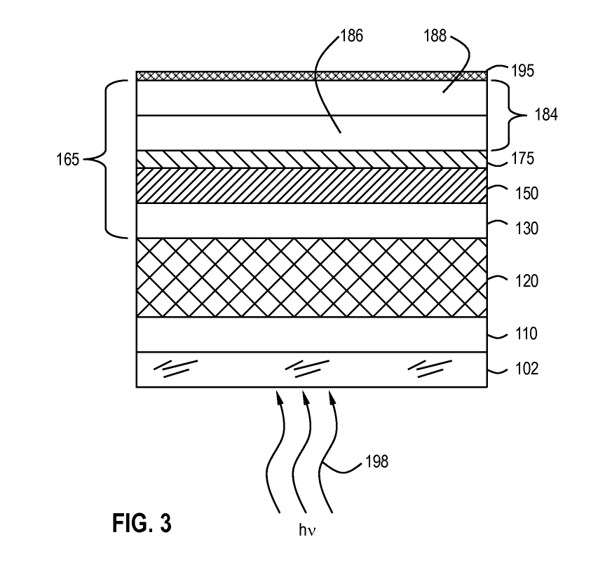

Additional embodiments of the invention are directed to photovoltaic modules 200 comprising a plurality of photovoltaic cells 201. FIG. 4 shows a photovoltaic module 200 according to various embodiments of the invention. The photovoltaic module 200 shown in FIG. 4 is a simplistic model comprising two photovoltaic cells 201. This is merely illustrative and should not be taken as limiting the scope of the invention. Typical photovoltaic modules 200 can have any number of individual cells 201. In detailed embodiments, the photovoltaic module 200 has about 100 individual cells 201. In specific embodiments, the photovoltaic module 200 has about 220 individual cells 201.

Briefly, the photovoltaic module 200 comprises a superstrate 102 which is substantially transparent to relevant wavelengths of incident light 198 as described previously. A front contact layer 110 is deposited over the superstrate 102 by known methods and is often made of a transparent conductive oxide. A light absorbing layer 120 is deposited on the front contact layer 110 by known methods and often comprises multiple sublayers to build a single-junction or tandem-junction solar cell, as described previously. In specific embodiments, the light absorbing layer 120 comprises one or more of an n-type, a p-type and an intrinsic layer. A back contact stack 165 comprising a back contact conductive layer 130 in contact with the light absorbing layer 120, a reflective layer 150 on the back contact conductive layer 130, a barrier layer 175 on the reflective layer 150 and a passivation layer 184 on the barrier layer 175. A busswire 195 (shown here as a cross-buss) connects the adjacent photovoltaic cells 201 by connecting to the passivation layer 184 of the back contact stack 165. The individual photovoltaic cells 201 may be manufactured as continuous layers covering the superstrate 102. The individual photovoltaic cells 201 can be separated from the continuous layers using various techniques including, but not limited to, laser ablation.

In specific embodiments, there is no glue layer, or intervening layer, between the back contact conductive layer 130 and the reflective layer 150.

According to detailed embodiments of the invention there is substantially no delamination of the reflective layer 150 from the back contact conductive layer 130 upon connecting the busswire 195 using high temperatures and/or solder flux.

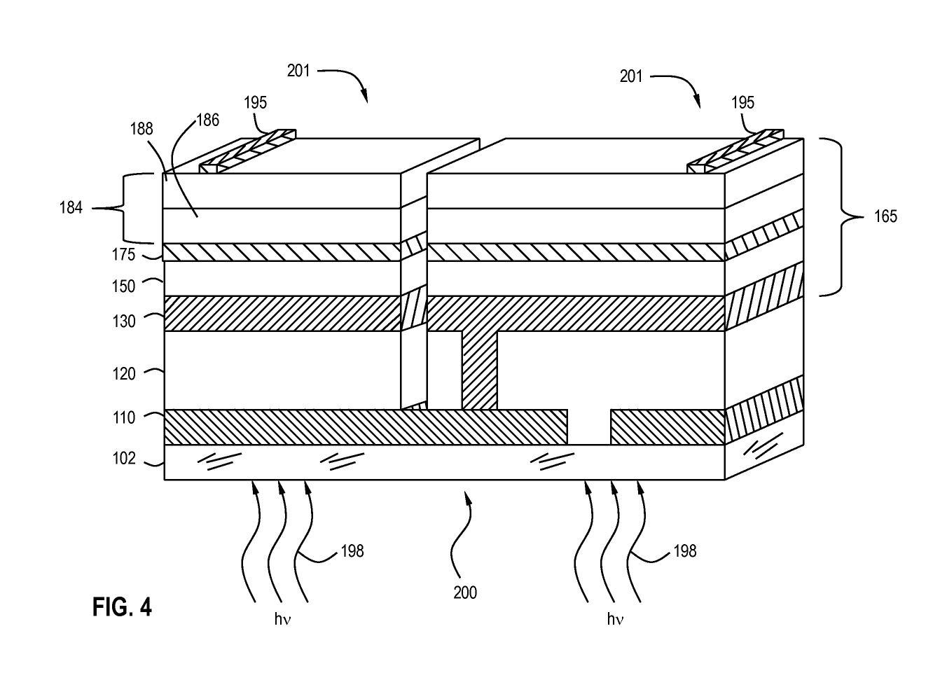

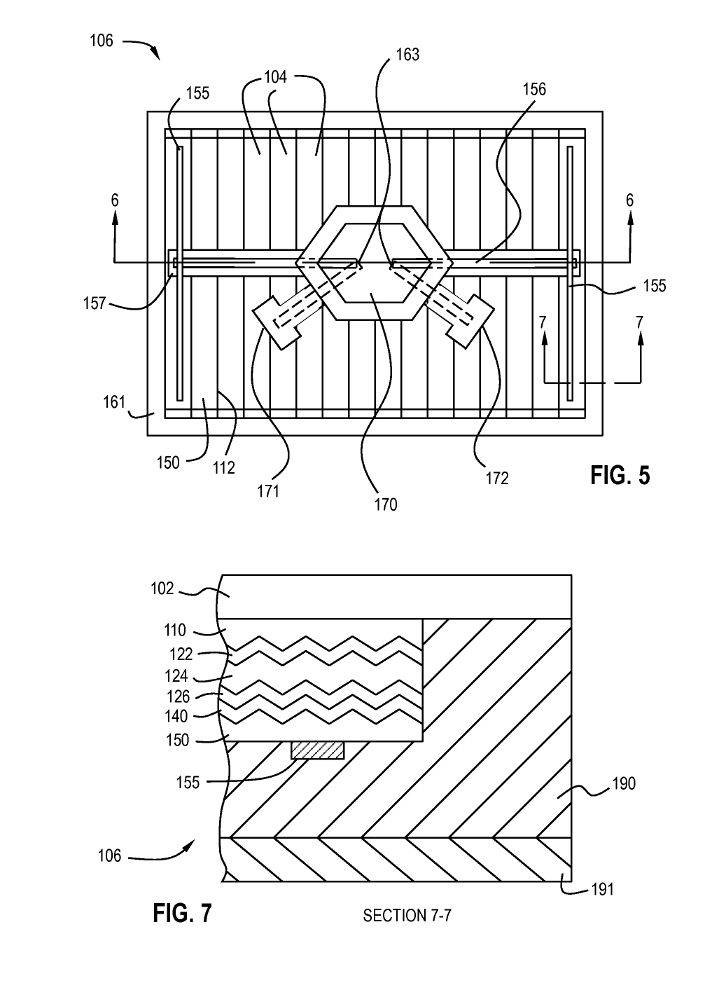

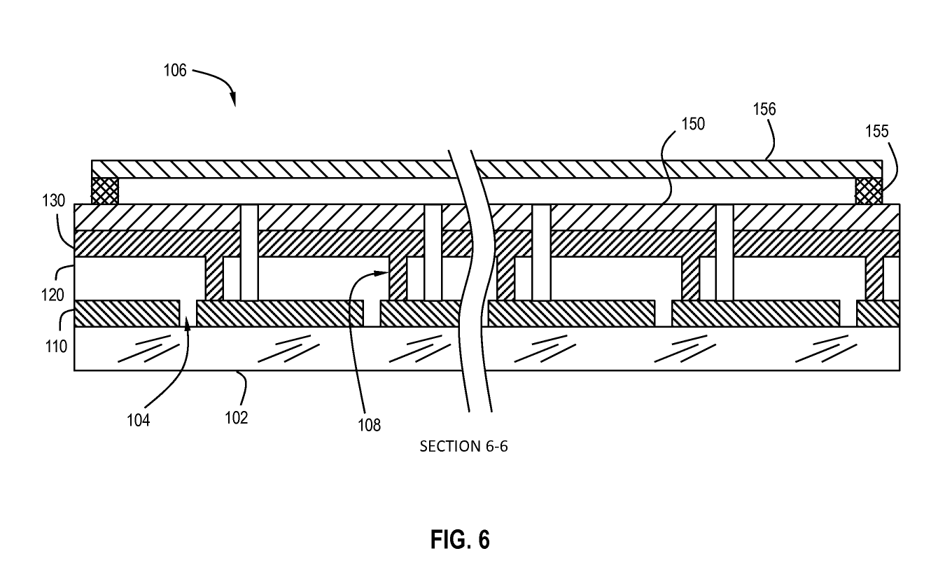

FIG. 5 shows a plan view that schematically illustrates an example of the rear surface of a formed solar cell module 106 produced by the previously described procedure. FIG. 6 is a side cross-sectional view of the solar cell module 106 illustrated in FIG. 5 (see section 6-6). FIG. 7 is a side cross-sectional view of a portion of the solar cell module 106 illustrated in FIG. 5 (see section 7-7). While FIG. 7 illustrates the cross-section of a single junction cell similar to the configuration described in FIG. 2A, this is not intended to be limiting as to the scope of the invention described herein.

The solar cell module 106 shown in FIG. 5-7 contains a superstrate 102, the solar cell device elements (e.g., reference numerals 110-150), one or more internal electrical connections (e.g., side-buss 155, cross-buss 156), a layer of bonding material 190, a back glass substrate 191, and a junction box 170. The junction box 170 generally contains two junction box terminals 171, 172 that are electrically connected to the leads 162 of the solar cell module 106 through the side-buss 155 and the cross-buss 156, which are in electrical communication with the reflective layer 150 and active regions of the solar cell module 106. An edge delete region 161 is shown around the perimeter of the photovoltaic module 106

FIG. 6 is a schematic cross-section of a solar cell module 106 illustrating various scribed regions used to form the individual cells within the solar cell module 106. As illustrated in FIG. 6, the solar cell module 106 includes a transparent superstrate 102, a front contact layer 110, a first photoabsorber layer 120, a back contact conductive layer 130 and a reflective layer 150. Three laser scribes 104, 108, 112 produce trenches to form a high efficiency solar cell device. Although formed together on the superstrate 102, the individual cells are isolated from each other by the insulating trench 112 formed in the back contact conductive layer 130 and reflective layer 150. In addition, a scribe 108 trench is formed in the first photoabsorber layer 120 so that the reflective layer 150 is in electrical contact with the front contact layer 110 of the adjacent cell. In one embodiment, the P1 scribe line 104 is formed by the removal of a portion of the front contact layer 110 prior to the deposition of the first photoabsorber layer 120, back contact conductive layer 130 and reflective layer 150. Similarly, in one embodiment, the P2 scribe 108 forms a trench in the first photoabsorber layer 120 by the removal of a portion of the first photoabsorber layer 120 prior to the deposition of the back contact conductive layer 130 and the reflective layer 150. While a single junction type solar cell is illustrated in FIG. 6 this configuration is not intended to be limiting to the scope of the invention described herein.

In some embodiments, step 133 includes a bonding wire attach module which is used to form the side-buss 155 and cross-buss 156 on the formed back contact 150. In this configuration, the side-buss 155 may comprise a conductive material that can be affixed, bonded, and/or fused to the reflective layer 150 to form a robust electrical contact. In one embodiment, the side-buss 155 and cross-buss 156 each comprise a metal strip, such as copper tape, a nickel coated silver ribbon, a silver coated nickel ribbon, a tin coated copper ribbon, a nickel coated copper ribbon, or other conductive material that can carry current delivered by the solar cell module 106 and that can be reliably bonded to the reflective layer 150. In a specific embodiment, the metal strip is between about 2 mm and about 10 mm wide and between about 1 mm and about 3 mm thick.

The cross-buss 156, which is shown electrically connected to the side-buss 155, can be electrically isolated from the reflective layer 150 of the solar cell module 106 by use of an insulating material 157, such as an insulating tape. The ends of each of the cross-busses 156 generally have one or more leads 162 that are used to connect the side-buss 155 and the cross-buss 156 to the electrical connections found in a junction box 170, which is used to connect the formed solar cell module 106 to other external electrical components.

As best shown in the partial cross-section view of FIG. 7, in the next steps, step 133 and 133, a bonding material 190 and “back glass” substrate 191 is provided and applied. The back glass substrate 361 is bonded onto the device superstrate 102 formed in steps above by use of a laminating process. In a detailed embodiment of step 135, a polymeric material is placed between the back glass substrate 361 and the deposited layers on the device superstrate 102 to form a hermetic seal to prevent the environment from attacking the solar cell during its life.

The device superstrate 102, the back glass substrate 191, and the bonding material 190 are transported to a bonding module in which step 135 and step 139 are performed. Portions of these steps include lamination to bond the backside glass substrate 191 to the device substrate. In step 137, a bonding material 190, such as Polyvinyl Butyral (PVB) or Ethylene Vinyl Acetate (EVA), may be sandwiched between the backside glass substrate 191 and the device superstrate 102. Heat and pressure are applied to the structure to form a bonded and sealed device using various heating elements and other devices found in the bonding module. The device superstrate 102, the back glass substrate 191, and the bonding material 190 thus form a composite solar cell structure, as shown in FIG. 7 that at least partially encapsulates the active regions of the solar cell device. In some embodiments, at least one hole formed in the back glass substrate 191 remains at least partially uncovered by the bonding material 190 to allow portions of the cross-buss 156 or the side-buss 155 to remain exposed so that electrical connections can be made to these regions of the solar cell structure 106 in future steps.

Next the composite solar cell structure is transported to an autoclave module in which step 139, or autoclave steps are performed on the composite solar cell structure to remove trapped gasses in the bonded structure and assure that a good bond is formed. In step 137, a bonded solar cell structure is inserted in the processing region of the autoclave module where heat and high pressure gases are delivered to reduce the amount of trapped gas and improve the properties of the bond between the device superstrate 102, back glass substrate 191, and bonding material 190. The processes performed in the autoclave are also useful to assure that the stress in the glass and bonding layer (e.g., PVB layer) are more controlled to prevent future failures of the hermetic seal or failure of the glass due to the stress induced during the bonding/lamination process. It may be desirable to heat the device superstrate 102, back glass substrate 191, and bonding material 190 to a temperature that causes stress relaxation in one or more of the components in the formed solar cell structure.

Additional processing steps 141 may be performed, including but not limited to device testing, additional cleaning, attaching the device to a support structure, unloading modules from processing chambers and shipping.

Reference throughout this specification to “one embodiment,” “certain embodiments,” “one or more embodiments,” “an embodiment,” “one aspect,” “certain aspects,” “one or more embodiments” and “an aspect” means that a particular feature, structure, material, or characteristic described in connection with the embodiment is included in at least one embodiment of the invention. Thus, the appearances of the phrases such as “in one or more embodiments,” “in certain embodiments,” “in one embodiment,” “in an embodiment,” “according to one or more aspects,” “in an aspect,” etc., in various places throughout this specification are not necessarily referring to the same embodiment or aspect of the invention. Furthermore, the particular features, structures, materials, or characteristics may be combined in any suitable manner in one or more embodiments or aspects. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A back contact for a photovoltaic cell, the back contact comprising:
a back contact conductive layer in contact with a photovoltaic cell conductive layer;
a reflective layer on the back contact conductive layer;
a barrier layer on the reflective layer; and
a passivation layer on the barrier layer, the passivation layer having a similar coefficient of thermal expansion as a busswire which connects the back contact of the photovoltaic cell to at least one adjacent photovoltaic cell.

2. The back contact of claim 1, wherein there is no intervening layer between the back contact conductive layer and the reflective layer.

3. The back contact of claim 1, wherein the back contact conductive layer comprises ZnO:Al.

4. The back contact of claim 1, wherein the reflective layer comprises silver.

5. The back contact of claim 1, wherein the barrier layer comprises a metal selected from the group consisting of chromium, tantalum, titanium, nickel, palladium and cobalt.

6. The back contact of claim 1, wherein the barrier layer comprises titanium.

7. The back contact of claim 1, wherein the passivation layer comprises a first sublayer and a second sublayer.

8. The back contact of claim 7, wherein the first sublayer comprises aluminum that has a thickness greater than about 500 Å.

9. The back contact of claim 7, wherein the second sublayer comprises nickel vanadium that has a thickness in the range of about 350 Å to about 1000 Å.

10. The back contact of claim 1, wherein there is substantially no delamination of the reflective layer from the back contact conductive layer upon attaching the busswire to the back contact.

11. A photovoltaic module comprising:
a plurality of photovoltaic cells comprising:
a front contact;
a light absorbing layer comprising one or more of an n-type layer, a p-type layer and an intrinsic layer;
a back contact comprising:
a conductive layer in contact with the photovoltaic cell,
a reflective layer on the conductive layer,
a barrier layer on the reflective layer, and
a passivation layer on the barrier layer; and
a busswire connecting adjacent photovoltaic cells, the busswire being connected to the passivation layer of the back contact.

12. The photovoltaic cell of claim 11, wherein the back contact does not have a glue layer between the conductive layer and the reflective layer.

13. The photovoltaic cell of claim 11, wherein there is substantially no delamination of the reflective layer from the conductive layer.

14. The photovoltaic cell of claim 11, wherein the conductive layer comprises ZnO:Al, the reflective layer comprises silver, and the barrier layer comprises titanium.

15. The photovoltaic cell of claim 14, wherein the passivation layer comprises a first sublayer comprising aluminum and a second sublayer comprising nickel vanadium.

16. A method of manufacturing a solar cell, comprising:
depositing a solar film onto a superstrate, the solar film adapted to convert light energy into electrical current, the solar film including a front contact and at least one light absorbing layer;
depositing a back contact conductive layer on the solar film;
depositing a reflector layer on the back contact layer;
depositing a barrier layer on the reflector layer;
depositing a passivation layer on the barrier layer; and
soldering a busswire to the solar cell over the passivation layer, wherein soldering the busswire to the solar cell occurs at a temperature in the range of 350° C. to about 400° C. and causes substantially no delamination of the reflector layer from the back contact conductive layer.

17. The method of claim 16, wherein the back contact layer comprises ZnO:Al.

18. The method of claim 16, wherein the reflector layer comprises silver and the barrier layer comprises titanium.

19. The method of claim 16, wherein depositing the passivation layer comprises depositing a first passivation sublayer and a second passivation sublayer.

20. The method of claim 19, wherein the first passivation sublayer comprises aluminum, the second passivation sublayer comprises nickel vanadium, and the passivation layer comprises an aluminum alloy.
